(19) United States
(12) Patent Application Publication
(10) Pub. No.: US 2005/0151710 A1
(43) Pub. Date: Jul. 14, 2005

(54) Display element and image display device

(75) Inventors: Kazuo Sanada, Kanagawa (JP); Tsutomu Yokouchi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/935,721

(22) Filed: Sep. 8, 2004

(30) Foreign Application Priority Data
Sep. 8, 2003 (JP) 2003-315617

(51) Int. Cl. G09G 3/34; G03F 3/10

(52) U.S. Cl. 345/84

(57) ABSTRACT

A display element for displaying an image with an ink has an transparent substrate having a void space for containing the ink therein to form a display section. The space has the first opening and the second opening opposing to each other. The first opening communicates with an atmosphere via an atmosphere communicating passage. The second opening allows the ink to introduce to the space of the image display section from an ink supply passage. The atmosphere communicating passage is controlled to close by a sealing member, whereby the movement of the ink into the space is controlled. The plural display elements are arranged to form a display unit and the plural display units are arranged in a matrix to form an image display device for displaying an image with the ink.

### BACKGROUND OF THE INVENTION

The present invention relates to a display element using an ink, in particular, a display element used for a thin image display device such as a flat panel display and an image display device composed of a plurality of display elements.

Conventionally, a liquid crystal display device (LCD) has been widely used as an image display device of information terminal equipment such as a personal computer and a personal digital assistant (PDA) or a car navigation system. A liquid crystal display device using thin-film transistors (TFTs) is advantageous in its high response speed and its capability of displaying a clear color moving image. On the other hand, such a liquid crystal display device needs an illuminating light source such as a backlight. In addition, the utilization efficiency of light from the illuminating light source is low. Therefore, the liquid crystal display is disadvantageous in its large power consumption, the necessity of electric power for displaying an image, its small viewing angle and the like. Accordingly, various systems of an image display device have been proposed to substitute for the liquid crystal display device.

For example, the following display devices have been proposed. A large number of transparent cells are both vertically and horizontally arranged as display units, and image display of the display device is switched ON/OFF by controlling the filling/non-filling of each of the cells with a liquid having a color (for example, see JP 05-241515 A). Another proposed display device is such that a plurality of cells, each containing air bubbles and a colored liquid, are provided so that the adjacent cells partially overlap each other, and the colored liquid is driven by an electrostatic force so as to switch image display ON/OFF (for example, see JP 08-254962 A). Furthermore, in another proposed display device, a fluid having a different specific gravity from that of a liquid is introduced into the liquid, and an image is formed by taking advantage of the difference in specific gravity (for example, see JP 09-44107 A, JP 09-311654 A, and JP 10-260651 A). Furthermore, a display device, which uses an electrocapillary phenomenon to drive an ink, has also been proposed (for example, see JP 10-39799 A).

However, the display device for making control as to whether to fill the colored liquid or not for each cell as disclosed in JP 05-241515 A has a problem that the structure is complicated. The display device for electrostatically driving the liquid and the air bubbles in the cell as disclosed in JP 08-254962 A has a difficulty in increasing the size of a screen. Furthermore, the systems as disclosed in JP 09-44107 A, JP 09-311654 A and JP 10-260651 A are disadvantageously incapable of forming a clear image and retaining a formed image. Moreover, the system as disclosed in JP 10-39799 A is disadvantageous in that the size of a screen is hardly increased and its structure is complicated.

### SUMMARY OF THE INVENTION

The present invention has been made to solve the above problems and has an object to provide a display element and an image display device with a simple structure at low cost, which are capable of displaying a highly visible image, easily switching ON/OFF of color display, and increasing a size of a screen.

The invention provides a display element for displaying an image with an ink. The display element comprises: an image display section having a space for containing the ink therein which is surrounded by wall surfaces, at least a part of the wall surfaces being formed by a member having transparency to form a display surface; an atmosphere communicating passage having a first opening on the display surface, the first opening communicating with an atmosphere; an ink entrance passage having a second opening on the wall surface opposing to the display surface, for allowing the ink to pass through the second opening to the space in the image display section; an ink supply passage in communication with the ink entrance passage to supply the ink to the ink entrance passage; and control means for switching between a sealing state and a non-sealing state of the atmosphere communicating passage by a sealing member for closing the atmosphere communicating passage to control movement of the ink into the image display section.

In the display element the sealing member preferably comprises a liquid drop, and the control means comprises a liquid drop ejection head for discharging the liquid drop.

The sealing member can comprise one of a transparent and colorless liquid and a transparent and colorless gel.

The control means can include an air gun for blowing the liquid drop away with air. In the display element, the control means can comprise a scraper for removing the sealing member.

The image display section is preferably located at a front side, a member constituting the image display section is provided on a rear side opposed to the front side to be in contact with a member constituting the ink supply passage, and a layer having a light-shielding property is provided on at least a part of a contact surface of the member constituting the image display section. In the display element, a main portion of the space in the image display section is formed to have one of a cubic shape, a cuboid shape, and a barrel shape.

In the image display section, preferably, at least one of the wall surface of the space, a surface of a flow passage of the ink entrance passage, and a surface of a flow passage of the ink supply passage is partly subjected to an ink repellent treatment. The sealing member preferably has a non-affinity for the ink.

The invention also provides an image display device for displaying an image with an ink. The image display devi comprises a display unit matrix composed of a plurality of display units arranged in a matrix, the display units each including at least one display element arranged therein, the display unit including: an image display section having a space for containing the ink therein that is surrounded by wall surfaces, at least a part of the wall surfaces being formed by a member having transparency to form a display surface; an atmosphere communicating passage having a first opening on the display surface, the first opening communicating with an atmosphere; an ink entrance passage having a second opening on the wall surface facing the display surface, for allowing the ink to pass through the second opening to the space in the image display section; and an ink supply passage in communication with the ink entrance passage to supply the ink to the ink entrance passage; control means for scanning the plurality of display elements in the display unit matrix to selectively close the atmosphere communicating passage by the sealing member, to control movement of the ink into the image display section; and ink supply means for supplying the ink to the plurality of ink supply passages of the display unit matrix.

The invention provides a display element for displaying an image with an ink. The display element comprises: an image display section having a space for containing the ink therein that is surrounded by wall surfaces, at least a part of the wall surfaces being made of a member having transparency to form a display surface; an ink supply passage in which the ink unidirectionally moves; a branching passage branching from the ink supply passage to be connected to the image display section; a converging passage for connecting the image display section and the ink supply passage to each other separately from the branching passage, the converging passage being converged with the ink supply passage on a downstream side of a branching point of the branching passage from the ink supply passage in a moving direction of the ink; and control means provided at the branching point of the branching passage branching from the ink supply passage, for controlling movement of the ink into the branching passage.

In the display element, the control means comprises an electrostatic diaphragm. The control means may comprise a valve using a piezo-type element which controls movement of the ink. The control means may comprise a valve actuating by an electrostatic force which controls movement of the ink. The control means may comprise a valve actuating by a magnetic force which controls movement of the ink. The control means may also comprise a valve activated by external electric power which controls movement of the ink.

In the display element, a flow passage of each of the branching passage, the converging passage, and the ink supply passage has preferably a curved inner surface.

The invention also provides an image display device, comprising: a display unit matrix composed of a plurality of display units arranged in a matrix, the display units each including at least one display element arranged therein, for displaying an image with an ink. The display element includes: an image display section having a space for containing the ink therein that is surrounded by wall surfaces, at least a part of the wall surfaces being made of a member having transparency to form a display surface; an ink supply passage in which the ink unidirectionally moves; a branching passage branching from the ink supply passage to be connected to the image display section; a converging passage for connecting the image display section and the ink supply passage to each other separately from the branching passage, the converging passage being converged with the ink supply passage on a downstream side of a branching point of the branching passage from the ink supply passage in a moving direction of the ink; and control means provided at the branching point of the branching passage branching from the ink supply passage, for controlling movement of the ink into the branching passage; and driving means connected to the control means of the display element provided in the display unit, for driving at least one of the control means to form an image on the display unit matrix.

According to the present invention, a display element and an image display device with a simple structure at low cost, which are capable of displaying a highly visible image, easily switching ON/OFF of color display, and increasing the size of a screen, can be obtained.

This application claims priority on Japanese patent application No. 2003-315617, the entire contents of which are hereby incorporated by reference.

### BRIEF DESCRIPTION OF THE DRAWINGS

In the accompanying drawings:

FIG. 1 is a perspective view of a display element according to a first embodiment of the present invention;

FIG. 2 is a plan view of the display element according to the first embodiment of the present invention;

FIG. 3 is a vertical sectional view of the display element according to the first embodiment of the present invention;

FIGS. 4A to 4C are vertical sectional views, each showing an operating state of the display element according to the first embodiment of the present invention;

FIG. 5 is a plan view of an image display device according to a second embodiment of the present invention;

FIG. 6 is a perspective view of a display element according to a third embodiment of the present invention;

FIG. 7 is a plan view of the display element according to the third embodiment of the present invention;

FIG. 8 is a vertical sectional view of the display element according to the third embodiment of the present invention;

FIGS. 9A to 9D are vertical sectional views, each showing an operating state of the display element according to the third embodiment of the present invention; and

FIG. 10 is a plan view of an image display device according to a fourth embodiment of the present invention.

### DETAILED DESCRIPTION OF THE PREFERRED EMBODIMENT

### First Embodiment

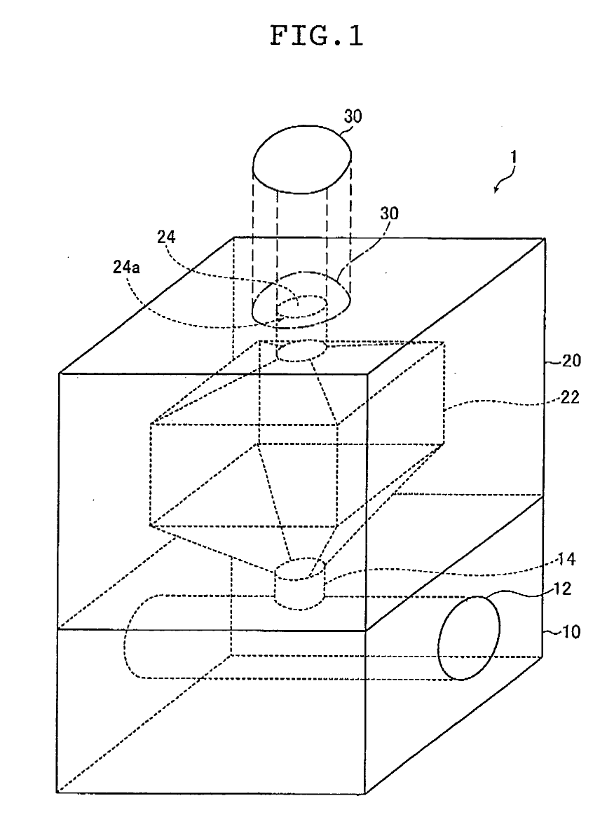

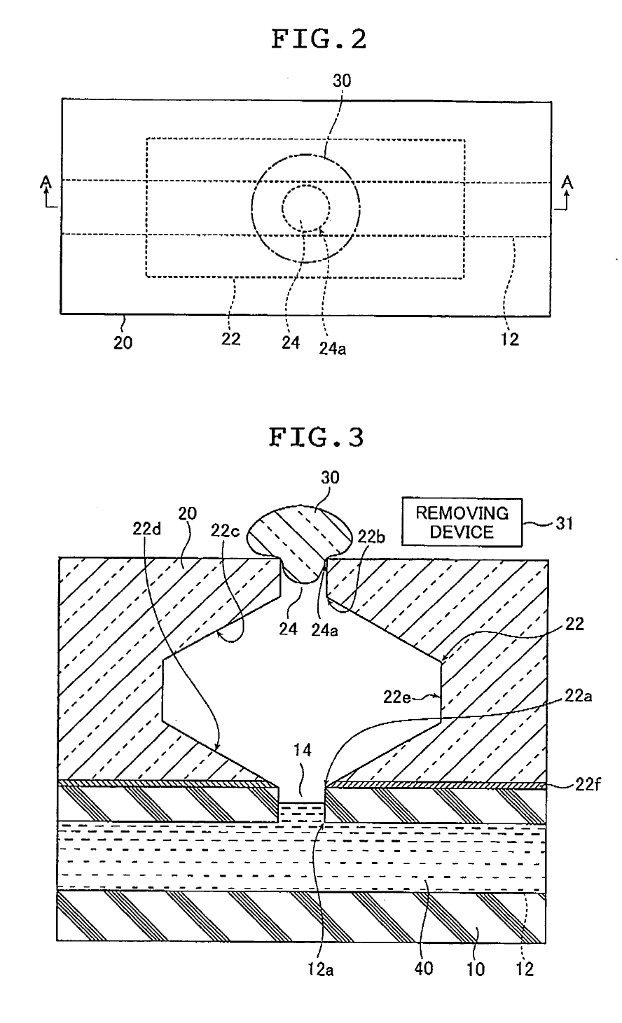

Hereinafter, a display element according to a first embodiment of the present invention will be described. FIG. 1 is a perspective view showing a display element 1 according to the first embodiment. FIG. 2 is a plan view showing the display element 1, and FIG. 3 is a vertical sectional view of the display element 1 taken along a plane perpendicular to a paper plane, passing through a line A-A in FIG. 2.

As shown in FIGS. 1 to 3, in the display element 1 according to the first embodiment, a transparent substrate 20 is provided on a support substrate 10 made of a material having a light-shielding property. In the support substrate 10, an ink supply passage 12 is provided in a direction along a surface of the support substrate 10, that is, a horizontal direction in FIGS. 2 and 3. In the approximate center of the transparent substrate 20, an image display section 22 forming a void space is provided. The shape of the image display section 22 is not particularly limited. As the shape of the image display section 22, however, the image display section including a main portion of the space formed in a cubic shape, a cuboid shape or a barrel shape is preferred. Herein, the main portion of the image display section designates a void space circumscribed by wall surfaces, the space being surrounded by lateral wall surfaces extending downwardly from an upper end surface corresponding to a display surface and two horizontal planes connected to the lateral wall surfaces at the upper side and the lower side thereof. As an example, a shape having a large volume of the main portion at the center and tapered at the top and the bottom can be given. More specifically, a shape formed by combining pyramids provided on a top surface and a bottom surface of a cube or a cuboid of the main portion or by combining cones provided on a top surface and a bottom surface of a barrel of the main portion can be used. Shapes as shown in FIGS. 1 and 3 are preferred.

The display element 1 according to this embodiment includes an upper wall surface of the image display section 22, which serves as a display surface 22c for color display of an ink. The display element 1 includes: an opening 22b corresponding to a first opening on a display surface 22c; and an atmosphere communicating passage 24 for bringing the opening 22b into communication with the atmosphere. More specifically, the opening 22b is provided in the approximate center of the display surface 22c. An open end 24a is provided on the upper surface of the transparent substrate 20. The atmosphere communicating passage 24 connecting the opening 22b and the open end 24a with each other is formed so as to bring the opening 22b of the image display section 22 into communication with the exterior of the display element 1, that is, the atmosphere.

The display element 1 includes an opening 22a corresponding to a second opening on a wall surface opposed to the atmosphere communicating passage 24. An ink entrance passage 14 for allowing an ink 40 to move into the image display section 22 is also formed. More specifically, the opening 22a is provided in the approximate center of a lower wall surface 22d. An opening 12a is provided on the upper part of the ink supply passage 12. The ink entrance passage 14 is formed between the opening 22a and the opening 12a so that the ink 40 is supplied through the ink supply passage 12 to the image display section 22.

In the display element 1 according to this embodiment, the movement of the ink 40 into the image display section 22 is controlled by switching between the closure and the non-closure of the atmosphere communicating passage 24 with a sealing member. More specifically, a cap 30 corresponding to the sealing member is provided on the open end 24a at the upper end of the atmosphere communicating passage 24 as needed. The cap 30 provided on the open end 24a closes the atmosphere communicating passage 24 to seal the space of the image display section 22. The cap 30 can be provided detachably on the open end 24a at the upper end of the atmosphere communicating passage 24. Any sealing member is used as the cap 30 as long as it can reliably seal the image display section 22; its shape and material are not particularly limited. For example, a shape such as a liquid drop or a gel and a material such as a resin can be given by way of example. It is preferred that the cap 30 is transparent and colorless. It is preferred that the cap 30 has a non-affinity for the ink 40 described below.

As a material for forming the cap 30, for the oil ink 40, hydrophobic materials such as aliphatic hydrocarbon, glycol ether, and higher alkyl alcohol can be given as examples. On the other hand, hydrophilic materials such as lower alkyl alcohol and an aqueous liquid can be given as examples for the oil ink 40.

The closure of the atmosphere communicating passage 24 with the cap 30 is achieved by a control device. Any means can be used as the control device as long as it can switch between the closure and the non-closure of the atmosphere communicating passage 24 with the sealing member, and therefore is not particularly limited. For example, if the liquid drop cap 30 is used as the sealing member, an ink ejection head or the like can be given as an example of means for providing the cap 30 on the open end 24a of the atmospheric communicating passage 24. As a device 31 for removing the cap 30 provided on the open end 24a, an air gun, a scraper and the like can be given as examples.

Although a material for forming the support substrate 10 is not particularly limited, a material having an ink resistance is preferably used. Silicon, a metal plate including an insulating film formed thereon, a resin and the like are given as examples. Alternatively, the support substrate 10 including the ink supply passage 12 may be formed by using the combination of a plurality of the materials mentioned above. A thickness of the support substrate 10 may be any value as long as it allows the formation of the ink supply passage 12, and therefore is not particularly limited. Typically, the support substrate 10 having a thickness of 50 to 1,000 μm is used. It is preferred to use the support substrate 10 having a thickness of about 200 μm.

It is preferred that, for example, a white or black layer 22f having a light-shielding property is provided on a contact surface of the member (the transparent substrate 20) constituting the image display section 22 with the member (the support substrate 10) constituting the ink supply passage 12, that is, above at least a part of an upper surface of the support substrate 10. For example, the following structures are given as examples: the support substrate 10 itself is made of a material having a light-shielding property; a layer having a light-shielding property is provided on the entire upper surface of the support substrate 10; and a layer having a light-shielding property is formed only on a part of the upper surface of the support substrate 10, which is situated directly above the ink supply passage 12. By providing the layer having a light-shielding property at least on a part of the upper surface of the support substrate 10 as described above, a color of the ink 40 in the ink support passage 12 is prevented from being displayed through the upper surface of the transparent substrate 20.

As a material for forming the transparent substrate 20, any material having a visible-light transmitting property and an ink resistance may be used as long as it can hermitically seal the space of the image display section 22 containing the ink when it is provided on the upper surface of the support substrate 10. Therefore, the material of the transparent substrate 20 is not particularly limited; glass, acrylic and the like are given as examples. A thickness of the transparent substrate 20 is not particularly limited as long as it is greater than a height of the image display section 22. Typically, the transparent substrate 20 having a thickness of 10 to 1,000 μm is used. It is preferred to use the transparent substrate 20 having a thickness of about 100 μm.

The ink 40 used in the present invention is not particularly limited. For example, a known colored ink 40 used for an ink jet printer can be used. It is preferred that at least one of a wall surface of the image display section 22, a surface of a flow passage of the ink entrance passage 14 and a surface of a flow passage of the ink supply passage 12 includes a portion that is subjected to an ink repellent treatment. Herein, the “ink repellent treatment” means a treatment for imparting a property of repelling an ink. For example, if a water-based ink is used, a water repellent treatment corresponds to the “ink repellent treatment”. On the other hand, if an oil-based ink is used, a hydrophilic treatment corresponds to the “ink repellent treatment”.

A method of conducting the ink repellent treatment is not particularly limited. As examples of the water repellent treatment corresponding to a type of ink repellent treatment, a method of applying a fluorine-based water repellent agent such as Cytop (registered trademark), a method of conducting a fluorine plasma treatment and the like can be given. The ink repellent treatment conducted on the wall surface or the surface of the flow passage can reduce the possibility that the ink 40 residing in the vicinity of the opening 22a may be solidified to hinder the flow of the ink 40. Moreover, since the repellency of the ink 40 to the wall surface of the image display section 22 and the surface of the flow passage of the ink supply passage 12 is improved, it is effective in that a quick response can be attained when the ink 40 draws back from the wall surface of the image display section 22, the surface of the flow passage of the ink entrance passage 14 and the surface of the flow passage of the ink supply passage 12.

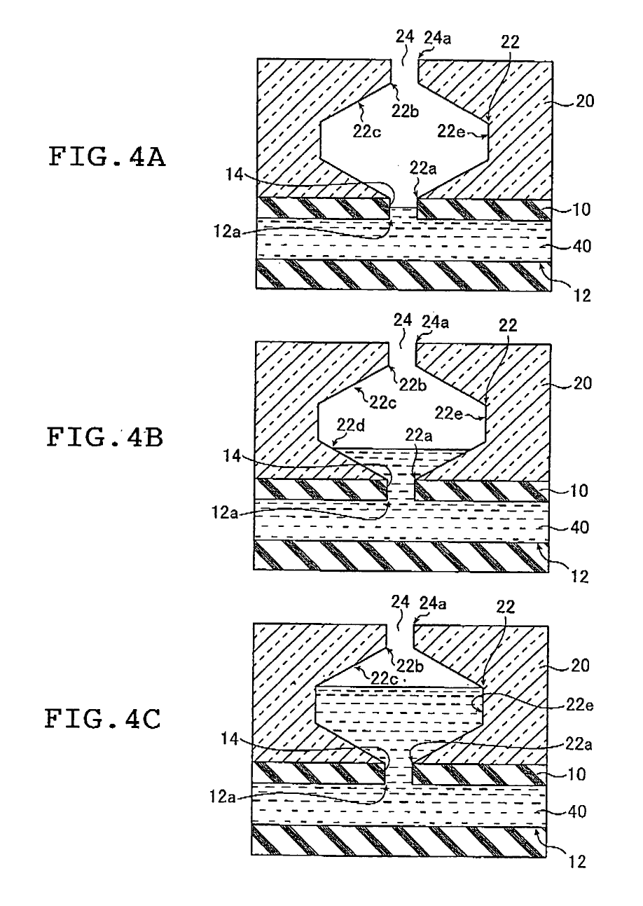

Next, how to operate in the display element 1 according to the present invention will be described. FIGS. 4A to 4C are vertical sectional views, each showing an operating state of the display element 1 according to the present invention. FIG. 4A shows a state where the ink 40 has not moved into the image display section 22 yet and therefore the color of the ink 40 is not displayed on the display surface 22c, that is, a “color display OFF” state. Since the support substrate 10 is made of a light-shielding material, a color of the light-shielding material such as white or black and a color given by the ink 40 in the ink entrance passage 14 are displayed on the display surface 22c in this state. The opening area of the opening 22a where the ink 40 stays to perform color display is extremely small. Thus, since the area of color display achieved by the ink 40 is extremely small, the color display by the ink 40 is substantially negligible in this state.

Next, the ink 40 in the ink supply passage 12 is pressurized by, for example, a pressure pump not shown in the state shown in FIG. 4A, that is, in the state where the cap 30 does not close the atmosphere communicating passage 24. Then, the ink 40 in the ink supply passage 12 is pressurized to gradually move into the image display section 22 through the ink entrance passage 14 and the opening 22a, thereby raising a surface level of the ink 40. FIG. 4B shows this state. As illustrated in FIG. 4B, when the pressure acting on the ink 40 increases, the ink 40 moves into the image display section 22 through the opening 22a.

As the ink 40 moves into the image display section 22, the amount of the ink 40 present in the image display section 22 increases. At this time, the volume of a space between the display surface 22c and the surface level of the ink 40 present in the image display section 22 (hereinafter, the space is referred to as an “upper space in the image display section 22”) reduces. However, the atmosphere communicating passage 24 extending from the upper part of the image display section 22 remains unclosed, and therefore the upper space in the image display section 22 is open to the atmosphere. As a result, an air pressure of the upper space in the image display section 22 is kept to the atmospheric pressure, so that the ink 40 moves into the image display section 22.

As the pressure acting on the ink 40 increases, the surface level of the ink 40 rises. At this time, since the lower wall surface 22d of the image display section 22 is slant, an area of the liquid surface of the ink 40 increases as the surface level of the ink 40 rises. As a result, an area of the display surface 22c, on which color display is performed, increases. In this manner, while the surface level of the ink 40 is rising along the lower wall surface 22d of the image display section 22, the area of color display achieved by the ink 40 on the display surface 22c increases in proportional to a rise of the surface level of the ink 40. Accordingly, by controlling an output of the pressurizing apparatus such as a pump for pressurizing the ink 40, the area of color display achieved by the colored ink 40 can be varied. Therefore, if the display surface 22c of the display element 1 is used as a pixel of an image to be displayed, that is, the minimum unit for constituting an image, a color tone can be achieved by modulating the color display area as described above.

Then, when the surface level of the ink 40 further rises, the surface level of the ink 40 reaches a lateral wall surface 22e of the image display section 22. FIG. 4C shows this state, that is, a “color display ON” state. Since the upper space in the image display section 22 is open to the atmosphere through the atmosphere communicating passage 24 even while the surface level of the ink 40 keeps rising smoothly. Even if the surface level of the ink 40 further rises from the state shown in FIG. 4C, the surface area of the ink 40 does not become larger than the area of a cross section of the space of the image display section 22 as long as the surface level of the ink 40 keeps within a range of the height of the lateral wall surface 22e. Therefore, the area of color display achieved by the surface of the ink 40 is kept constant. Moreover, since the surface level of the ink 40 is kept at the level of the opening 22b having a small opening area compared to the area of the image display section 22, the surface level of the ink 40 does not exceed the level of the opening 22b so as to be clipped. As a result, the ink 40 can be prevented from leaking from the display element 1.

Next, the case where a color once displayed is to be cleared will be described. The state shown in FIG. 4C corresponds to the state where the ink 40 is allowed to move in and to reach the lateral wall surface 22e of the image display section 22 of the display element 1 so as to achieve color display with the maximum display area of the color display. In this state, the pressure pump (not shown) of the ink 40 continues pressurizing the ink 40. In order to clear a displayed color, that is, to achieve the “color display OFF” state, the pressure of the ink 40 in the ink supply passage 12 is reduced to the atmospheric pressure or lower so as to discharge the ink 40 from the display element 1 to the outside.

When the pressure of the ink 40 is reduced to the atmospheric pressure or lower so as to discharge the ink 40 from the display element 1 to the outside, the surface level of the ink 40 gradually lowers. When the surface level of the ink 40 lowers, the state shifts from the state shown in FIG. 4C through the state shown in FIG. 4B finally to the state shown in FIG. 4A. Even while the surface level of the ink 40 is lowering, the volume of the upper space in the image display section 22 varies. However, the atmosphere communicating passage 24 is still open to the atmosphere as in the case where the surface level of the ink 40 is rising. Therefore, the air pressure of the upper space in the image display section 22 is always kept to the atmospheric pressure. As a result, since the surface level of the ink 40 smoothly lowers even when the color display is switched OFF, a quick response can be obtained upon switching the color display from ON to OFF.

As described above, in the state where the atmosphere communicating passage 24 is not closed without providing the cap 30 on the open end 24a at the upper end of the atmosphere communicating passage 24, the upper space in the image display section 22 is open to the atmosphere through the atmosphere communicating passage 24. Thus, simply by increasing or reducing the pressure of the ink 40 in the ink supply passage 12, an ON/OFF state of the color display of the image display section 22 can be controlled. Moreover, by regulating the pressure of the ink 40 to adjust the amount of the ink 40 that is allowed to move into the image display section 22, the color tone representation can be achieved by area modulation.

Next, the state where the atmosphere communicating passage 24 is closed by the cap 30. While the cap 30 is provided on the open end 24a at the upper end of the atmosphere communicating passage 24, the atmosphere communicating passage 24 is closed as shown in FIG. 3 so that the upper space in the image display section 22 is not open to the atmosphere. Accordingly, when the ink 40 in the ink supply passage 12 is pressurized, a pressure of air in the upper space in the image display section 22 increases. Since an increase in air pressure acts so that the surface level of the ink 40 is pushed in a downward direction of the FIG. 3, the ink 40 can hardly move into the image display section 22. Therefore, the ink 40 does not fill the image display section 22, thereby keeping the color display OFF state shown in FIG. 3.

As described above, by providing or not providing the cap 30 on the open end 24a (by closing or not closing the atmosphere communicating passage 24), the ink 40 is controlled to move into or not to move into the image display section 22. Specifically, in the display element 1 in which the atmosphere communicating passage 24 is not closed by the cap 30, the ink 40 can move into the image display section 22. Therefore, the display element 1 has the function of performing color display on the display surface 22c. On the other hand, in the display element 1 in which the atmosphere communicating passage 24 is closed by the cap 30, the ink 40 cannot move into the image display section 22. Therefore, the display element 1 does not have the function of performing color display on the display surface 22c.

A plurality of the display elements 1 are arranged in a matrix to form an image display device. Then, for example, a device (control device) such as an ink ejection head is used to close by the caps 30 only the atmosphere communicating passages 24 of the display elements 1, for which the ink 40 is not required to move into the image display sections 22, that is, for which the color display OFF state is to be achieved, while the atmosphere communicating passages 24 of the display elements 1, for which the color display ON state is to be achieved, remain unclosed. By pressurizing the ink 40 in the ink supply passage 12 in this state, only the display elements for which color display is desired to be achieved are brought into the color display ON state. In this manner, the image display device is formed, in which a plurality of display surfaces of the display elements in the color display ON state cooperatively display one image.

As described above, according to the display element of the present invention, by switching between the closed state and the unclosed state of the atmosphere communicating passage 24 by the cap 30, the color display ON/OFF is controlled. The device (control means) of placing and removing the cap 30 can be provided outside the part where the color display is actually performed, such as the image display section 22, the atmosphere communicating passage 24, the ink supply passage 12 and the ink entrance passage 14. Accordingly, the structure where the color display is actually performed as described above can be simplified. Moreover, since the ink 40 is allowed to move into the image display section 22 to achieve the color display, highly visible color display with a high reflectance and a wide viewing angle can be achieved. Furthermore, by arranging a plurality of the display elements 1 in a matrix, a highly visible image can be formed.

Furthermore, since the structure where the color display is actually performed such as the image display section 22, the atmosphere communicating passage 24, the ink supply passage 12 and the ink entrance passage 14 is simplified, the production cost can be kept low. As a result, an inexpensive display element can be produced. Moreover, since the ink 40 moves into and is discharged from the image display section 22 in a reversible manner and a closing/unclosing operation of the atmosphere communicating passage 24 by the cap 30 is repeatable, the color display can be repeatedly switched ON and OFF. Furthermore, since the structure, in which the color display is actually performed, is simplified, the size of the display screen can be easily increased. Moreover, an illuminating light source such as a backlight can be omitted, the power consumption can be kept low if no illuminating light source is used.

### Second Embodiment

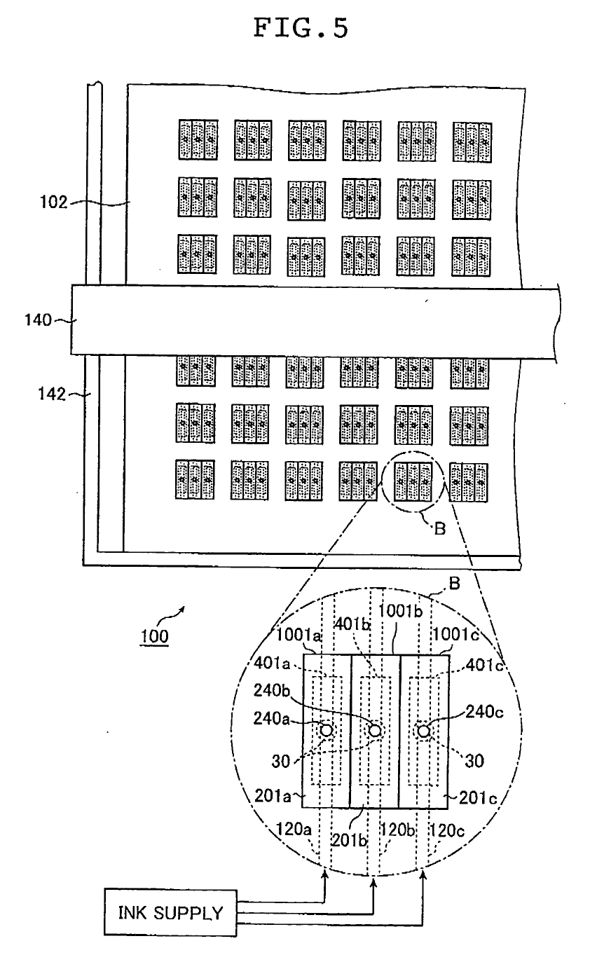

A second embodiment of the present invention will now be described. In this second embodiment, a plurality of the display elements 1 according to the first embodiment are arranged to form a display unit. Then, a plurality of the thus formed display units are arranged in a matrix to form an image display device. FIG. 5 shows a schematic structure of an image display device 100 according to the second embodiment. As illustrated in FIG. 5, a plurality of display units are arranged in a matrix on a substrate 102 in the image display device 100. For each of the display units, a plurality of the display elements 1 described above, for example, three display elements are arranged so as to be adjacent to each other.

A small circle B shown in FIG. 5 is a partially enlarged view of-one of the display units arranged in the image display device 100. As shown in the small circle B shown in FIG. 5, each of the display units is composed of three display elements 1001a, 1001b and 1001c. For example, color display is performed so that the display element 1001a corresponds to R (red), the display element 1001b corresponds to G (green), and the display element 1001c corresponds to B (blue). The color display is performed as the entire display unit.

As illustrated in FIG. 5, the display elements 1001a, 1001b and 1001c include image display sections 401a, 401b and 401c in transparent substrates 201a, 201b and 201c, respectively, as in the case of the display element 1 according to the first embodiment described above. Open ends 240a, 240b and 240c are formed for the respective image display sections 401a, 401b and 401c. Ink supply passages 120a, 120b and 120c are respectively formed for the display elements 1001a, 1001b and 1001c. The inks 40 corresponding to the respective colors are supplied to the ink supply passages 120a, 120b and 120c; for example, an R(red) ink is supplied to the ink supply passage 120a, a G (green) ink is supplied to the ink supply passage 120b, and a B (blue) ink is supplied to the ink supply passage 120c.

On an upper surface of the substrate 102, an elongated band-like ink jet arm 140 is provided so as to move on a rail 142 provided along one side of the substrate 102. A plurality of ink jet nozzles (not shown) are formed on a bottom surface of the ink jet arm 140. These ink jet nozzles place the caps 30 on the open ends 240a, 240b, 240c, . . . , of the display elements 1001a, 1001b, 1001c, . . . , respectively, as needed. Moreover, an air jet nozzle (not shown) is provided for a part of the ink jet arm 140 so as to be opposed to each of the display elements 1001a, 1001b, 1001c, . . . , so as to remove the caps 30 placed on the open ends 240a, 240b, 240c, . . . , of the respective display elements 1001a, 1001b, 1001c, . . . , by blowing them away with an air jet.

In order to allow the image display device 100 according to this embodiment to display an image, the ink jet arm 140 is first made to scan the substrate 102 based on an image signal of an image to be displayed so that atmosphere communicating passages of the display elements among the display elements 1001a, 1001b, 1001c and so on, which are not allowed to perform the color display, are closed by the caps 30. Next, the inks in the ink supply passages 120a, 120b and 120c are pressurized by a ink supply unit in this state. Then, the inks move only into the image display sections 401 (401a, 401b, 401c and so on) of the display elements whose atmosphere communicating passages are not closed by the caps 30, thereby performing the color display. As a result, an image based on image information is formed on the image display device including the display surface of the display element performing the color display as one pixel.

As described above, a plurality of the display elements according to the first embodiment of the present invention are arranged to form the display unit. Then, a plurality of the thus formed display units are arranged in a matrix. By selectively closing the atmosphere communicating passages with the caps 30 by the ink jet arm 140, the image display device 100 capable of forming a color image can be obtained. In the image display device 100, it is the ink jet arm 140 that has the function of controlling ON/OFF of the color display of each of the display elements 1001a, 1001b, 1001c, and so on. Therefore, the structure of the portion that actually performs the color display can be simplified.

In this embodiment, three display elements 1001a to 1001c constituting one display unit are horizontally laid out, that is, are arranged parallel each other on the surface of the image display device 100 so that the display elements perform the color display of R (red), G (green) and B (blue), respectively. However, the arrangement of the display elements is not limited thereto.

For example, three display elements are piled up in a thickness direction of the image display device. The display elements are made to display C (cyan), M (magenta) and Y (yellow), thus forming the image display device capable of performing color display. In this case, a support substrate made of a transparent material is used. In addition, a layer having a light-shielding property is provided on a part of the upper surface of the support substrate which is situated directly above the ink supply passage. Furthermore, three display elements are piled up so that their horizontal positions (in a direction parallel to the top surface of the image display device) of the image display sections are aligned with each other, so that the image display sections of the respective display devices partially overlap with each other when observed from the top surface of the image display device. In addition, the openings of the respective display elements are provided on the top surface of the image display device.

Alternatively, a color filter for transmitting light of a specific color is provided on each of the display elements of the image display device 100 shown in FIG. 5. Thus, the image display device, for which color display is controlled ON/OFF by controlling a light-shielding liquid to move into or to be discharged from the image display section of each of the display elements, can be formed.

For example, an R (red) color filter (not shown) is provided on the display element 1001a shown in the small circle B illustrated in FIG. 5. Similarly, a G (red) color filter (not shown) is provided on the display element 1001b, and a B (blue) color filter (not shown) is provided on the display element 1001c. In this manner, one display unit is formed. The arrangement of a plurality of the thus formed display units in a matrix on the substrate 102 in FIG. 5 is exemplified as the structure of the image display device. In this image display device, an opening is provided at the position in substantially the center of each of the color filters, which corresponds to the open end of each of the display elements, so as to be in communication with the open end of each of the display elements. Instead of the ink, a light-shielding liquid is supplied to each of the ink supply passages 120a, 120b and 120c. In this case, a transparent support substrate may be used to form a transmission type image display device in which light from an illuminating light source is radiated through a bottom surface of the support-substrate from back side. Alternatively, a light-reflective support substrate may be used to form a reflection type image display device.

### Third Embodiment

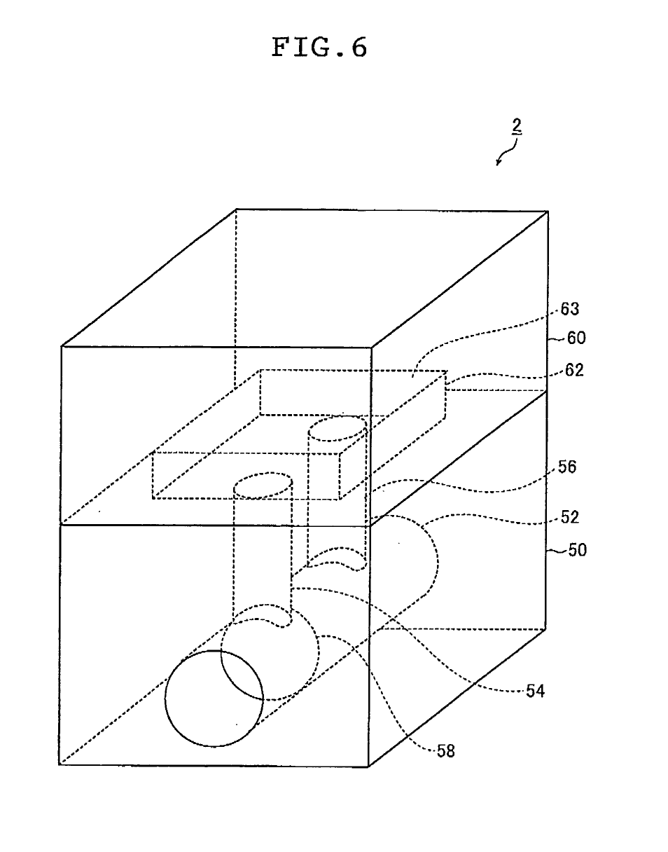

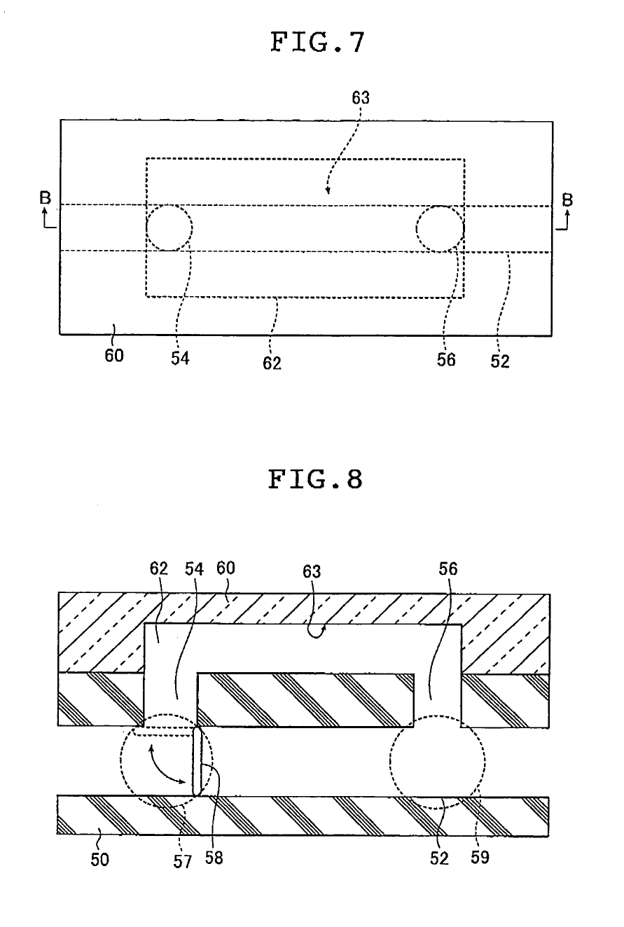

Hereinafter, a display element according to a third embodiment of the present invention will be described. FIG. 6 is a perspective view showing a display element 2 according to the third embodiment of the present invention. FIG. 7 is a plan view of the display element 2, and FIG. 8 is a vertical sectional view showing a cross section of the display element 2 cut along a plane perpendicular to the paper plane and passing through a line B-B of FIG. 7.

As shown in FIGS. 6 to 8, in the display element 2 according to this third embodiment, a transparent substrate 60 is provided on a support substrate 50 formed of a material having a light-shielding property. In the support substrate 50, an ink supply passage 52, through which an ink flows unidirectionally, is provided in a direction along a surface of the support substrate 50, that is, in a horizontal direction as shown in FIGS. 7 and 8.

An image display section 62 having a space is formed between an upper surface of the support substrate 50 and the transparent substrate 60 provided thereon. A display surface 63 is formed on an upper wall surface of the image display section 62. The shape of the image display section 62 is not particularly limited. For example, a cubic or cuboid-shaped space of the image display section 62 can be given as an example.

The image display section 62 and the ink supply passage 52 are connected to each other through two flow passages, i.e., a branching passage 54 and a converging passage 56. An end of the branching passage 54 (a lower end in FIG. 8) branches off from the ink supply passage 52 at a branching position 57, whereas the other end thereof (an upper end in FIG. 8) is connected to the image display section 62. An end of the converging passage 56 (an upper end in FIG. 8) is connected to the image display section 62, whereas the other end thereof (a lower end in FIG. 8) is connected to and converges with the ink supply passage 52 at a converging position 59 which is situated on the downstream side of the branching position 57 in a moving direction of the ink. More specifically, after a flow (of the ink 70) from the ink supply passage 52 branches off to the branching passage 54 at the branching position 58, the flow once moves into the image display section 62, before flowing into the converging passage 56 so as to move into the ink supply passage 52 again at the converged position 59.

As shown in FIG. 8, at the branching position 57 between the branching passage 54 and the ink supply passage 52, a switching element (control means) 58 for switching a moving direction of the ink 70 is provided. As the switching element 58, any switching element can be used without particular limitations as long as it can switch the moving direction of the ink 70 between the ink supply passage 52 and the branching passage 54. Specifically, for example, a valve activated by external electric power such as an electrostatic actuator, an electrostatic valve, a piezo valve, and an electrostatic diaphragm can be given as an example. In this embodiment, one switching element 58 is provided at the branching position 57 so as to control the opening/closure of the branching passage 54 and the ink supply passage 52. However, the structure of the switching element is not limited thereto. For example, an opening/closing device such as a valve may be provided at each of the branching passage 54 and the ink supply passage 52 between the branching position 57 and the converged position 59, where each of the opening/closing devices is independently activated.

A material for forming the support substrate 50 is not particularly limited. However, it is preferred to use a material having an ink resistance. For example, silicon, a metal plate including an insulating film formed thereon, a resin or the like are given as examples. The thickness of the support substrate 50 may be any value as long as it allows the formation of the ink supply passage 52, and therefore is not particularly limited. Typically, the support substrate 50 having a thickness of 50 to 1000 μm is used. It is preferred to use the support substrate 50 having a thickness of about 200 μm.

It is preferred that a layer having a light-shielding property be provided on at least a part of the support substrate 50. For example, the following structures are given as examples: the support substrate 50 itself is made of a material having a light-shielding property; a layer having a light-shielding property is provided on the entire upper surface of the support substrate 50 shown in FIGS. 7 and 8; and a layer having a light-shielding property is formed only on a portion of the upper surface of the support substrate 50 which is situated directly above the ink supply passage 52. By providing the layer having a light-shielding property at least on a part of the upper surface of the support substrate 50 as described above, a color of the ink 70 in the ink support passage 52 is prevented from being displayed through the upper surface of the transparent substrate 60.

As a material for forming the transparent substrate 60, any material having a visible-light transmitting property and an ink resistance may be used as long as it can hermetically hold the ink 70 in the image display section 62 when it is provided on the upper surface of the support substrate 50. Therefore, the material of the transparent substrate 60 is not particularly limited. For example, glass, acrylic and the like may be used. The thickness of the transparent substrate 60 is not particularly limited as long as it allows the formation of the image display section 62. Typically, the transparent substrate 60 having a thickness of 10 to 1000 μm is used. It is preferred to use the transparent substrate 60 having a thickness of about 100 μm.

The ink 70 used in the present invention is not particularly limited. For example, a known colored ink 70 used for an ink jet printer can be used. It is preferred that at least one of a wall surface of the image display section 62, a surface of a flow passage of the ink supply passage 52, a surface of a flow passage of the branching passage 54, and a surface of a flow passage of the converging passage 56 includes a portion that is subjected to an ink repellent treatment. Herein, the “ink repellent treatment” means a treatment for imparting an ink repelling property. For example, if a water-based ink is used, a water repellent treatment corresponds to the “ink repellent treatment”. On the other hand, if an oil-based ink is used, a hydrophilic treatment corresponds to the “ink repellent treatment”.

The method of conducting the ink repellent treatment is not particularly limited. For example, as examples of the water repellent treatment corresponding to a type of ink repellent treatment, a method of applying a fluorine-based repellent agent such as Cytop (registered trademark), a method of conducting a fluorine plasma treatment, and the like can be given. The ink repellent treatment conducted on the wall surface or the surface of the flow passage can reduce the possibility that the ink 70 residing in the image display section 62, the ink supply passage 52, the branching passage 54, and the converging passage 56 may be solidified to hinder the flow of the ink 70. Moreover, since the repellency of the ink 70 from the wall surface or the surface of the flow passage is improved, there is an effect in that a quick response can be attained when the ink 70 draws back from the wall surface or the surface of the flow passage.

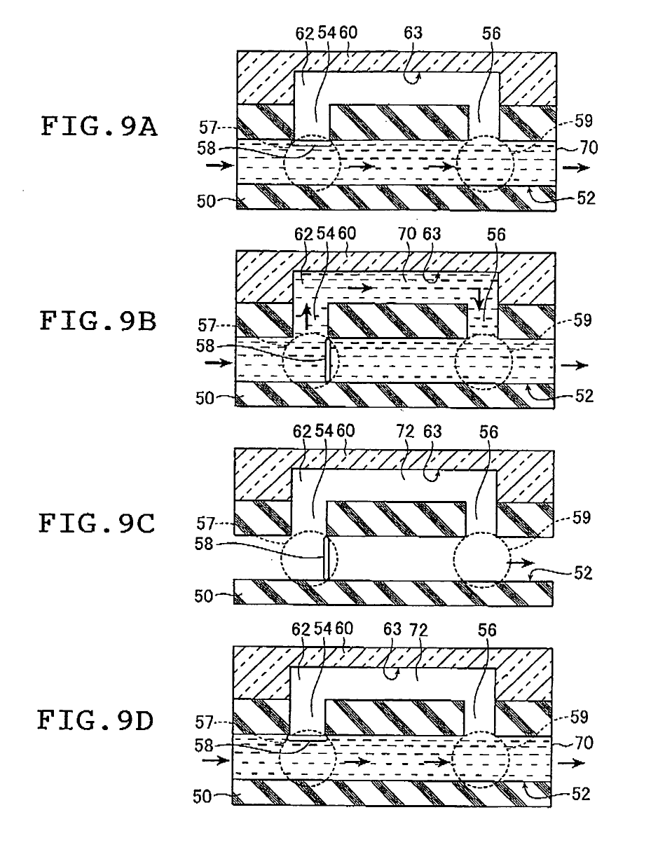

Next, how to operate in the display element 2 according to the third embodiment of the present invention will be described. FIGS. 9A to 9D are vertical sectional views, each showing an operating state of the display element 2 according to the present invention. FIG. 9A shows the state before the display element 2 according to this embodiment performs display, that is, a “color display OFF” state.

In this state, the switching element 58 opens the ink supply passage 52 side while closing the branching passage 54 side at the branching position 57. As a result, at the branching position 57, the ink 70 flows through the ink supply passage 52 in a downstream direction (in a direction indicated by arrows in FIG. 9A) without flowing into the branching passage 54. Therefore, as shown in FIG. 9A, the ink 70 does not move into the image display 62. As a result, color display is not performed on the display surface 63 by the ink 70.

Next, the display element 2 according to this embodiment is activated to be switched from a state where color display is not performed (the color display OFF state) to a state where color display is performed (the color display ON state). As shown in FIG. 9B, for the above switching, the switching element 58 is activated to close the ink supply passage 52 side and to open the branching passage 54 side at the branching position 57. Then, a moving direction of the ink 70 flowing through the ink supply passage 52 is changed toward the branching passage 54 so that the ink 70 flows into the branching passage 54.

The ink 70 flowing into the branching passage 54 moves into the image display section 62 situated on the downstream side of the branching passage 54 to fill the image display section 62. FIG. 9B shows this state. As shown in FIG. 9B, since the image display section 62 is filled with the ink 70, the color display with the ink 70 is performed on the display surface 63 to achieve the color display ON state.

Next, an operation for switching the display element 2, which is once brought into the color display ON state, to the color display OFF state will be described. In order to switch the display element 2 from the color display ON state shown in FIG. 9B to the color display OFF state, it is required to discharge the ink 70 from the image display section 62. Therefore, without activating the switching element 58, that is, while keeping the ink supply passage 52 side closed and keeping the branching passage 54 side open at the branching position 57, the ink 70 present in the image display section 62 is discharged.

As examples of a method of discharging the ink 70 from the image display section 62, a method of sucking the ink from the downstream side of the ink supply passage 52, that is, from the right side in FIG. 9B at a pressure equal to or lower than the atmospheric pressure to discharge the ink 70, a method of allowing a transparent and colorless liquid (or gas) 72 or the like to flow through the ink supply passage 52 from its upstream side (from the left side in FIG. 9B), and the like are given. In any case, the ink 70 flowing into the image display section 62 is discharged via the converging passage 56 and the converged position 59 to the ink supply passage 52. This state is shown in FIG. 9C.

Next, at the branching position 57, the switching element 58 is activated to open the ink supply passage 52 side and to close the branching passage 54 side. As shown in FIG. 9D, when the ink 70 is allowed to flow into the ink supply passage 52 in this state, the ink 70 flows into the ink supply passage 52 to achieve the same state as that shown in FIG. 9A (the color display OFF state).

As described above in detail, in the display element 2 according to this embodiment, the ink supply passage 52 and the image display section 62 are connected with each other through the branching passage 54 and the converging passage 56. A moving direction of the ink 70 is switched by the switching element 58 provided at the branching position 57 to control ON and OFF of the color display. As a result, the display element 2 having a simple structure can be obtained. Moreover, since the ink 70 is allowed to move into the image display section 62 to perform the color display, highly visible color display with a high reflectance and a wide viewing angle can be achieved. Furthermore, by the arrangement of a plurality of the display elements 2, a highly visible image can be formed.

Furthermore, since the structure of the portion in which the ink 70 actually moves, such as the image display section 62, the ink supply passage 52, the branching passage 54, and the converging passage 56 is simplified, the production cost can be kept down. As a result, an inexpensive display element can be produced. Moreover, since the entering and discharging of the ink 70 are reversible with each other and the operation of the switching element 58 is also reversible and repeatable, the color display can be repeatedly switched ON and OFF. Furthermore, since the structure of the portion, in which the ink 70 actually moves, such as the image display section 62, the ink supply passage 52, the branching passage 54, and the converging passage 56 is simplified, the size of a display screen can be easily increased. Moreover, an illuminating light source such as a backlight can be omitted; the power consumption can be kept down if no illuminating light source is used.

### Fourth Embodiment

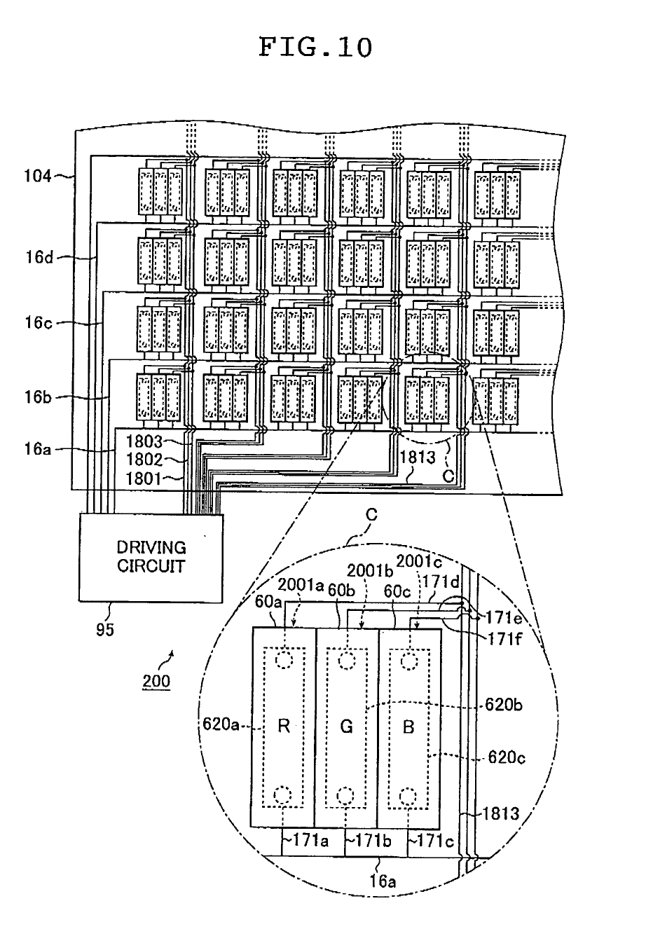

A fourth embodiment of the present invention will now be described. In this embodiment, a plurality of the display elements according to the above-described third embodiment are arranged to form a single display unit. A plurality of the thus formed display units are arranged in a matrix to form an image display device. FIG. 10 shows a schematic structure of an image display device 200 according to the fourth embodiment of the present invention. As illustrated in FIG. 10, a plurality of display units are arranged in a matrix on a substrate 104 in the image display device 200. For each of the display units, a plurality of the display elements 2 described above, for example, the three display elements 2 are arranged so as to be adjacent to each other.

FIG. 10 shows in a small circle C, a partially enlarged view of one of the display units arranged in the image display device 200. As shown in the small circle C of FIG. 10, each of the display units is composed of three display elements 2001a, 2001b, and 2001c. For example, an ink supply passage (not shown) for supplying an R (red) ink is provided below the display element 2001a, an ink supply passage (not shown) for supplying a G (green) ink is provided below the display element 2001b, and an ink supply passage (not shown) for supplying a B (blue) ink is provided below the display element 2001c. The color display is performed so that the display element 2001a corresponds to R (red), the display element 2001b corresponds to G (green), and the display element 2001c corresponds to B (blue). The color display is performed in the entire display unit.

As illustrated in FIG. 10, the display elements 2001a, 2001b, and 2001c include image display sections 620a, 620b, and 620c in transparent substrates 60a, 60b, and 60c, respectively, as in the case of the display element 2 according to the third embodiment described above. At a branching position of each of the image display sections, a switching element (not shown) is provided. Wiring lines 171a and 171d, 171b and 171e, and 171c and 171f are connected to the display elements 2001a to 2001c, respectively. The respective display elements 2001a to 2001c are connected to horizontal wiring lines 16a, 16b, 16c, 16d, and so on and vertical wiring lines 1801, 1802, 1803, and so on through the wiring lines 171a to 171f. On the other end sides, the display elements 2001a to 2001c are connected to a driving circuit 95. By allowing a current to flow through the horizontal wiring line 16 and the vertical wiring line 18 connected to the switching element of the display element for which color display is to be performed, an arbitrary display element is made to perform the color display.

For example, in order to allow the image display device 2001a shown in the small circle C in FIG. 10 to perform the color display, the driving circuit 95 allows a electric current to flow through the horizontal wiring line 16 (16a) connected to the switching element through the wiring line 171a and the vertical wiring line 18 (1813) connected to the switching element through the wiring line 171d, so that the switching element is driven to perform the color display with the R (red) ink on a display surface of the image display section 620a. Similarly, the display element 2001b performs color display with the G (green) ink, and the display element 2001c performs color display with the B (blue) ink.

In order to allow the image display device 200 according to the fourth embodiment to display an image, the R (red) ink is allowed to move into or be discharged from the display element 2001a, the G (green) ink is allowed to move into or be discharged from the display element 2001b, and the B (blue) ink is allowed to move into or be discharged from the display element 2001c based on an image signal of an image to be displayed.

As described above, a plurality of the display elements according to the present invention are arranged to form the display unit. Then, a plurality of the thus formed display units are arranged in a matrix so as to be driven by the driving circuit 95. As a result, the image display device capable of forming a color image can be obtained. In the image display device as described above, the switching element is provided for the image display section of each of the display elements. Simply by driving the switching element, the ink can be made to smoothly flow to obtain a quick response.

In this embodiment, a single pixel is divided into three in a horizontal direction, that is, in a direction parallel to a surface of the image display device to provide the three display elements 2001a to 2001c so that the respective display elements perform color display of R (red), G (green) and B (blue), respectively. However, the structure of the display elements is not limited thereto. For example, a plurality of display elements are piled up in a thickness direction of the image display device. The display elements are made to display C (cyan), M (magenta), and Y (yellow), respectively. The image display device capable of performing the color display with such a structure can be formed. In this case, a support substrate made of transparent material is used. In addition, it is preferred that a layer having a light-shielding property is provided on a part of the upper surface of the support substrate, which is situated directly above the ink supply passage, so that the ink in the ink supply passage is not visible. Furthermore, three display elements are piled up so that their horizontal positions (in a direction parallel to the top surface of the image display device) of the image display sections are aligned with each other to partially overlap the image display sections of the respective display elements with each other when an image is observed from the top surface of the image display device.

Alternatively, a color filter for transmitting light of a specific color is provided on each of the display elements of the image display device 200 shown in FIG. 10. The image display device, for which color display is ON/OFF-controlled by controlling a light-shielding liquid to move into or to be discharged from the image display section of each of the display elements, can be formed. For example, an R (red) color filter (not shown) is provided on the display element 2001a shown in the small circle C of FIG. 10. Similarly, a G (green) color filter (not shown) is provided on the display element 2001b, and a B (blue) color filter (not shown) is provided on the display element 2001c. In this manner, one display unit is formed. The arrangement of the thus formed display units in a matrix on the substrate 104 in FIG. 10 is exemplified as the structure of the image display device. In this image display device, instead of the ink, a light-shielding liquid is supplied to each of the ink supply passages. In this case, a transparent support substrate may be used so as to form a transmission type image display device in which light from an illuminating light source is applied through a bottom surface of the support substrate from back side. Alternatively, a light-reflective support substrate may be used to form a reflection type image display device.

1. A display element for displaying an image with an ink, comprising:
an image display section having a space for containing the ink therein which is surrounded by wall surfaces, at least a part of the wall surfaces being formed by a member having transparency to form a display surface;
an atmosphere communicating passage having a first opening on the display surface, the first opening communicating with an atmosphere;
an ink entrance passage having a second opening on the wall surface opposing to the display surface, for allowing the ink to pass through the second opening to the space in said image display section;
an ink supply passage in communication with the ink entrance passage to supply the ink to the ink entrance passage; and
control means for switching between a sealing state and a non-sealing state of said atmosphere communicating passage by a sealing member for closing said atmosphere communicating passage to control movement of the ink into said image display section.

2. The display element according to claim 1, wherein said sealing member comprises a liquid drop, and said control means comprises a liquid drop ejection head for discharging the liquid drop.

3. The display element according to claim 1, wherein said sealing member comprises one of a transparent and colorless liquid and a transparent and colorless gel.

4. The display element according to claim 2, wherein said control means includes an air gun for blowing the liquid drop away with air.

5. The display element according to claim 1, wherein said control means comprises a scraper for removing said sealing member.

6. The display element according to claim 1, wherein, provided that said image display section is located at a front side, a member constituting said image display section is provided on a rear side opposed to the front side to be in contact with a member constituting the ink supply passage, and a layer having a light-shielding property is provided on at least a part of a contact surface of said member constituting said image display section.

7. The display element according to claim 1, wherein, a main portion of the space in said image display section is formed to have one of a cubic shape, a cuboid shape, and a barrel shape.

8. The display element according to claim 1, wherein, at least one of the wall surface of the space in said image display section, a surface of a flow passage of the ink entrance passage, and a surface of a flow passage of the ink supply passage is partly subjected to an ink repellent treatment.

9. The display element according to claim 1, wherein said sealing member has a non-affinity for the ink.

10. An image display device for displaying an image with an ink, comprising:
a display unit matrix composed of a plurality of display units arranged in a matrix, said display units each including at least one display element arranged therein, said display unit including:
an image display section having a space for containing the ink therein that is surrounded by wall surfaces, at least a part of the wall surfaces being formed by a member having transparency to form a display surface;
an atmosphere communicating passage having a first opening on the display surface, the first opening communicating with an atmosphere;
an ink entrance passage having a second opening on the wall surface facing the display surface, for allowing the ink to pass through the second opening to the space in said image display section; and
an ink supply passage in communication with the ink entrance passage to supply the ink to the ink entrance passage;
control means for scanning said plurality of display elements in said display unit matrix to selectively close said atmosphere communicating passage by said sealing member, to control movement of the ink into said image display section; and
ink supply means for supplying the ink to said plurality of ink supply passages of said display unit matrix.

11. A display element for displaying an image with an ink, comprising:
an image display section having a space for containing the ink therein that is surrounded by wall surfaces, at least a part of the wall surfaces being made of a member having transparency to form a display surface;
an ink supply passage in which the ink unidirectionally moves;
a branching passage branching from the ink supply passage to be connected to said image display section;
a converging passage for connecting said image display section and the ink supply passage to each other separately from said branching passage, said converging passage being converged with the ink supply passage on a downstream side of a branching point of said branching passage from the ink supply passage in a moving direction of the ink; and
control means provided at the branching point of said branching passage branching from the ink supply passage, for controlling movement of the ink into said branching passage.

12. The display element according to claim 11, wherein said control means comprises an electrostatic diaphragm.

13. The display element according to claim 11, wherein said control means comprises a valve using a piezo-type element which controls movement of the ink.

14. The display element according to claim 11, wherein said control means comprises a valve actuating by an electrostatic force which controls movement of the ink.

15. The display element according to claim 11, wherein said control means comprises a valve actuating by a magnetic force which controls movement of the ink.

16. The display element according to claim 11, wherein said control means comprises a valve activated by external electric power which controls movement of the ink.

17. The display element according to claim 11, wherein a flow passage of each of said branching passage, said converging passage, and the ink supply passage has a curved inner surface.

18. An image display device, comprising:
a display unit matrix composed of a plurality of display units arranged in a matrix, said display units each including at least one display element arranged therein, for displaying an image with an ink, said display element including:
an image display section having a space for containing the ink therein that is surrounded by wall surfaces, at least a part of the wall surfaces being made of a member having transparency to form a display surface;
an ink supply passage in which the ink unidirectionally moves;
a branching passage branching from the ink supply passage to be connected to said image display section;
a converging passage for connecting said image display section and the ink supply passage to each other separately from said branching passage, said converging passage being converged with the ink supply passage on a downstream side of a branching point of said branching passage from the ink supply passage in a moving direction of the ink; and
control means provided at the branching point of said branching passage branching from the ink supply passage, for controlling movement of the ink into said branching passage; and
driving means connected to said control means of said display element provided in said display unit, for driving at least one of said control means to form an image on said display unit matrix.
